(19) United States
(12) Patent Application Publication
(10) Pub. No.: US 2025/0159863 A1
(43) Pub. Date: May 15, 2025

(54) VERTICAL GATE DRAM DEVICE

(71) Applicant: Yangtze Memory Technologies Co., Ltd., Wuhan (CN)

(72) Inventors: Chao SUN, Wuhan (CN); Ning JIANG, Wuhan (CN); Wei LIU, Wuhan (CN)

(73) Assignee: Yangtze Memory Technologies Co., Ltd., Wuhan, Hubei (CN)

(21) Appl. No.: 18/516,159

(22) Filed: Nov. 21, 2023

(30) Foreign Application Priority Data
Nov. 9, 2023 (CN) 202311493928.3

(51) Int. Cl. H10B 12/00

(52) U.S. Cl. CPC H10B 12/05; H10B 12/315

(57) ABSTRACT

A method of fabricating a semiconductor device can include providing a substrate, etching the substrate from a first side to form at least one vertical pillar having a first and a second end, forming at least one gate line on a gate dielectric layer formed on sidewalls of the at least one vertical pillar, forming a first p-type region at the first end of the at least one vertical pillar, forming a storage unit connecting the first p-type region, removing a portion of the substrate at a second side opposite to the first side of the substrate to expose the second end of the at least one vertical pillar, forming a second p-type region made of at least p-type SiGe at the second end of the at least one vertical pillar, and forming a bit line in connection with the second p-type region.

### INCORPORATION BY REFERENCE

This present application claims the benefit of Chinese Patent Application No. 202311493928.3, filed on Nov. 9, 2023, which is incorporated herein by reference in its entirety.

### TECHNICAL FIELD

The present disclosure relates to a semiconductor device and the fabrication process thereof. The semiconductor device can be a vertical gate dynamic random access memory (DRAM) device.

### BACKGROUND

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit. A three-dimensional (3D) memory architecture can be employed to address the density limitation in planar memory cells by using vertical gate transistors.

### SUMMARY

Aspects of the disclosure provide a method of fabricating a semiconductor device. The method can include providing a substrate, etching the substrate from a first side of the substrate to form at least one vertical pillar, the at least one vertical pillar has a first end and a second end opposite to the first end, forming at least one gate line on a gate dielectric layer formed on sidewalls of the at least one vertical pillar, forming a first p-type region at the first end of the at least one vertical pillar, forming a storage unit connecting the first p-type region, removing a portion of the substrate at a second side of the substrate to expose the second end of the at least one vertical pillar, the second side of the substrate being opposite to the first side of the substrate, forming a second p-type region at the second end of the at least one vertical pillar, the second p-type region is made of at least p-type silicon germanium (SiGe), and forming a bit line in connection with the second p-type region at the second end of the at least one vertical pillar.

In an embodiment, the forming the second p-type region further includes performing a rapid thermal anneal process with an annealing temperature of less than 500° C.

In an embodiment, the forming the second p-type region further includes epitaxing the p-type SiGe onto the at least one vertical pillar.

In an embodiment, the forming the second p-type region further includes depositing the p-type SiGe into the at least one vertical pillar.

In an embodiment, the first p-type region has a dopant concentration higher than 10¹⁹ atoms/cm³.

In an embodiment, the second p-type region has a dopant concentration higher than 10¹⁹ atoms/cm³.

In an embodiment, the at least one gate line and the bit line are formed so that they are perpendicular to each other.

In an embodiment, the second p-type region is made of p-type SiGe.

In an embodiment, the gate line is further encapsulated by an oxide layer.

In an embodiment, the storage unit is a capacitor.

Aspects of the disclosure provide a semiconductor device. The semiconductor device can include at least one vertical pillar, the at least one vertical pillar has a first end and a second end opposite to the first end, at least one gate line on a gate dielectric layer formed on sidewalls of the at least one vertical pillar, a first p-type region at the first end of the at least one vertical pillar, a storage unit connects with the first p-type region, a second p-type region at the second end of the at least one vertical pillar, the second p-type region comprises at least p-type silicon germanium (SiGe), and a bit line in connection with the second p-type region at the second end of the at least one vertical pillar.

Aspects of the disclosure provide a memory system that include the semiconductor device to store data.

### BRIEF DESCRIPTION OF THE DRAWINGS

Various embodiments of this disclosure that are proposed as examples will be described in detail with reference to the following figures, wherein like numerals reference like elements, and wherein:

FIG. 1 shows a side view of a cross-section of a memory device 100 according to an embodiment of the present disclosure.

FIGS. 2A-2I show a fabrication process of forming a DRAM array having vertical transistors 219 according to embodiments of the present disclosure.

FIG. 2J shows a top view of a substrate 200.

FIG. 3 shows a flowchart of a fabrication process 300 of forming a DRAM array having vertical transistors 219 according to embodiments of the present disclosure.

FIG. 4 shows a block diagram of an example system 400 with a memory system according to embodiments of the disclosure.

### DETAILED DESCRIPTION OF EMBODIMENTS

Transistors are used as the switch or selecting devices in the memory cells of some memory devices, such as DRAM, phase change memory (PCM), and ferroelectric DRAM (FRAM). Planar transistors commonly used in existing memory cells usually have a horizontal structure with buried word lines in the substrate and bit lines above the substrate. Since the source and drain of a planar transistor are disposed at different locations, which increases the area occupied by the transistor. The design of planar transistors also complicates the arrangement of interconnected structures, such as word lines and bit lines, coupled to the memory cells, for example, limiting the pitches of the word lines and/or bit lines, thereby increasing the fabrication complexity and reducing the production yield. Moreover, because the bit lines and the storage units (e.g., capacitors or PCM elements) are arranged on the same side of the planar transistors (above the transistors and substrate), the bit line process margin is limited by the storage units, and the coupling capacitance between the bit lines and storage units, such as capacitors, are increased. Planar transistors may also suffer from a high leakage current as the saturated drain current keeps increasing, which is undesirable for the performance of memory devices.

On the other hand, as the number of memory cells keeps increasing, to maintain the same chip size, the dimensions of the components in the memory cell array, such as transistors, word lines, and/or bit lines, need to keep decreasing in order not to significantly reduce the memory cell array efficiency.

To address one or more of the aforementioned issues, vertical transistors are introduced to replace the conventional planar transistors as the switch and selecting devices in a memory cell array of memory devices (e.g., DRAM, PCM, and FRAM). Compared with planar transistors, the vertically arranged transistors (i.e., the drain and source are overlapped in the plan view) can reduce the area of the transistor as well as simplify the layout of the interconnect structures, e.g., metal wiring the word lines and bit lines, which can reduce the fabrication complexity and improve the yield. The vertical structures of the transistors also allow the bit lines and storage units, such as capacitors, to be arranged on opposite sides of the transistors in the vertical direction (e.g., one above and one below the transistors), such that the process margin of the bit lines can be increased and the coupling capacitance between the bit lines and the storage units can be decreased.

In an example, the process of fabrication of the vertical structures of the transistors for memory devices includes forming sources including n-type doped regions at the top end of vertical transistors and forming storage units, such as capacitors, in contact with the sources. Then forming drains including n-type doped regions at the bottom end of the transistors for bit lines to connect. This way, the vertical transistors can have similar properties as n-type conventional planar transistors. However, to activate the n-type doped regions in the drains at the bottom end of the transistors, a high-temperature annealing process, such as rapid thermal annealing with an annealing temperature above 750° C. is required. The high-temperature annealing process could damage the capacitors that are already formed on the top end of the transistors. This would result in a potential performance drop in the memory device. The present disclosure introduces a solution in which p-type doped regions replace the n-type doped regions. More specifically, p-type Silicon Germanium (SiGe) is used in forming the p-type doped regions in the vertical transistors that are connected to the bit lines.

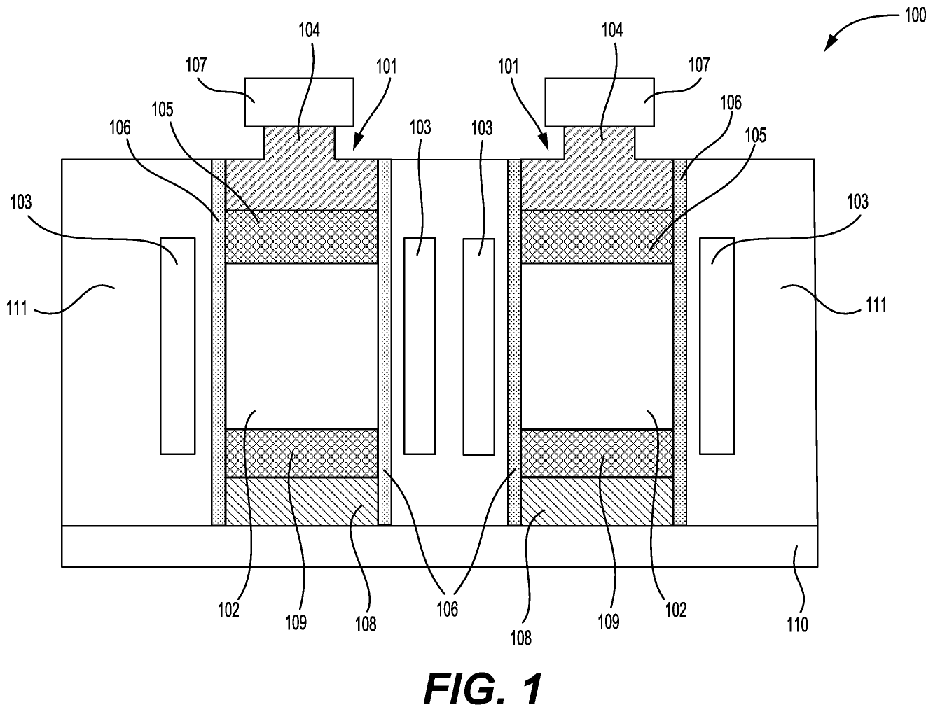

FIG. 1 shows a side view of a cross-section of a memory device 100 according to an embodiment of the present disclosure. The memory device 100 includes multiple vertical transistors 101, gate lines 103, storage units 107, and bit lines 109. Each vertical transistor 101 includes a semiconductor body 102 which is connected to a gate structure (e.g., gate dielectric layer and gate layer) and includes a source, and a drain. The source can be located at a first end of the vertical transistor 101. The source can include a first p-type doped region 104. The first p-type doped region 104 can be a highly doped p-type region. The first p-type doped region 104 can connect to a first lightly doped drain (LDD) region 105. The drain can be located at a second end of the vertical transistor 101. The drain can include a second p-type doped region 108. The second p-type region can be a highly doped p-type region. The second p-type doped region can connect to a second LDD region 109. In an embodiment, the LDD regions 105 and 109 can have a dopant concentration lower than 10¹⁹ atoms/cm³. In an embodiment, the heavily-doped regions 104 and 108 can have a dopant concentration higher than 10¹⁹ atoms/cm³.

Each vertical transistor 101 can connect to a storage unit 107 at the source (e.g., the first p-type doped region 104). Each vertical transistor 101 can have gate structure that includes a gate dielectric layer 106 and a gate layer. The gate dielectric layer 106 is positioned in between the gate layer and the semiconductor body 102. The gate lines 103 can be formed by connecting the gate layer of each vertical transistor 101 in a row. The gate lines 103 can be enclosed by oxide 111 (e.g., silicon dioxide) to provide insulation. The gate lines 103 can also be refer to as word lines. Bit lines 110 can be connected to the drain at the second p-type doped region 108. The gate lines 103 and bit lines 110 can be formed in a way that is perpendicular to each other. The storage unit 107 can include any devices that are capable of storing binary data (e.g., 0 and 1), including but not limited to, capacitors for DRAM cells and FRAM cells, and PCM elements for PCM cells. In an embodiment, vertical transistor 101 controls the selection and/or the state switch of the respective storage unit 107 coupled to vertical transistor 101.

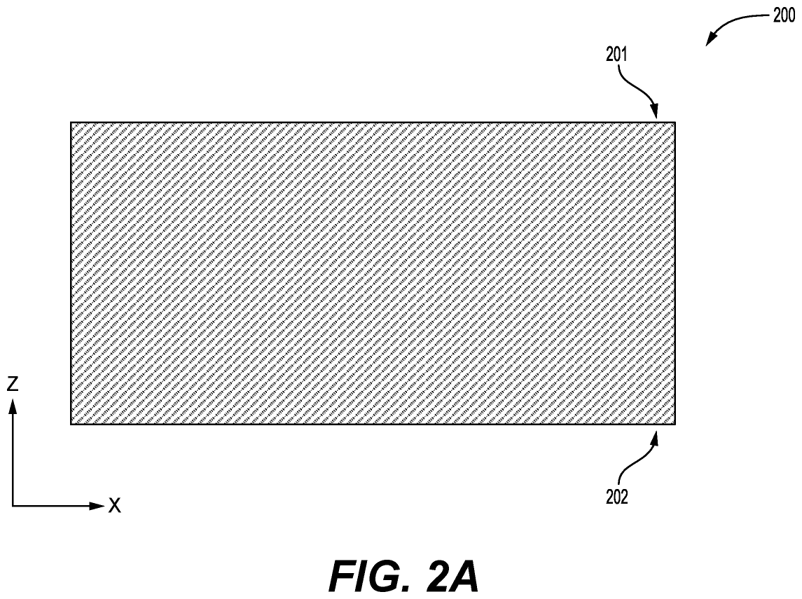

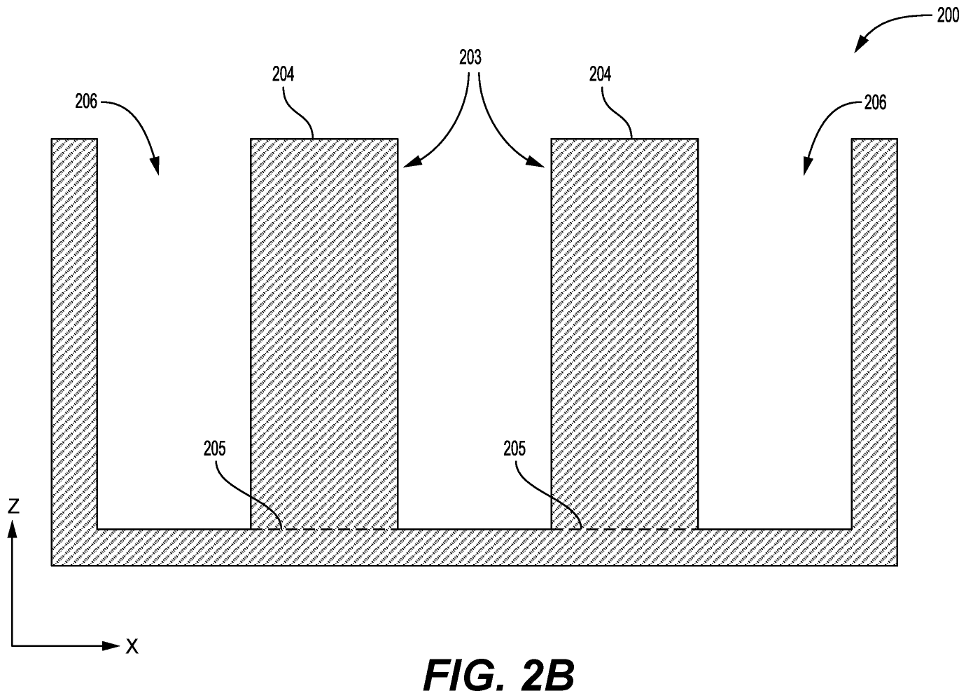

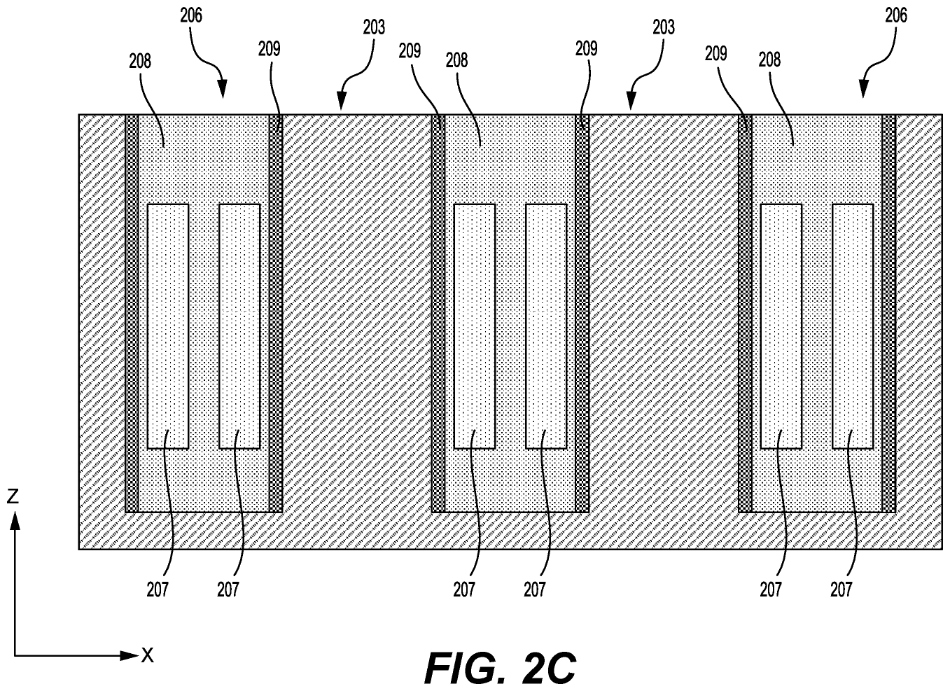

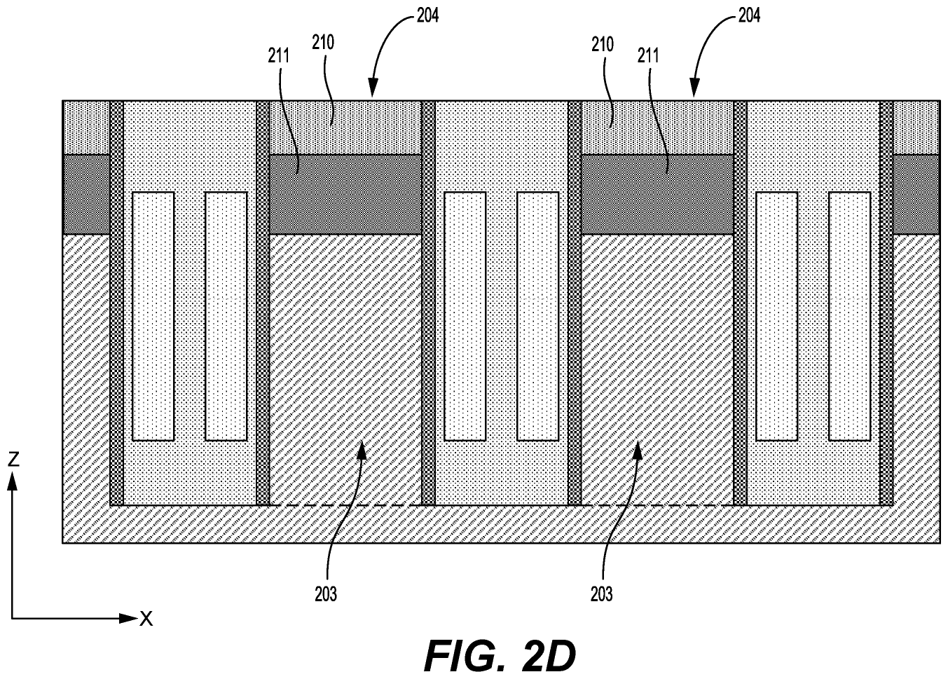

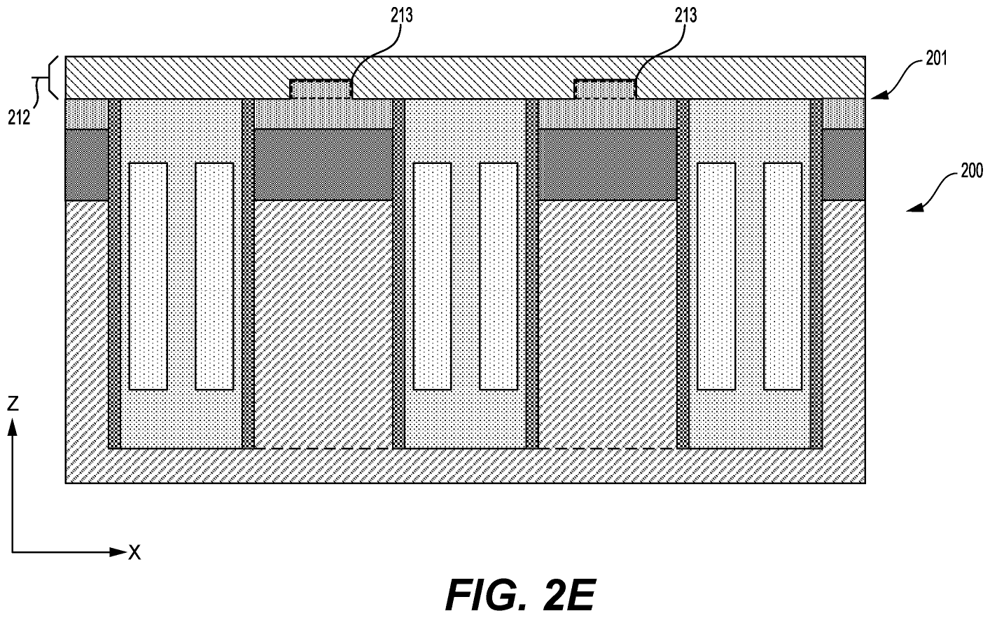

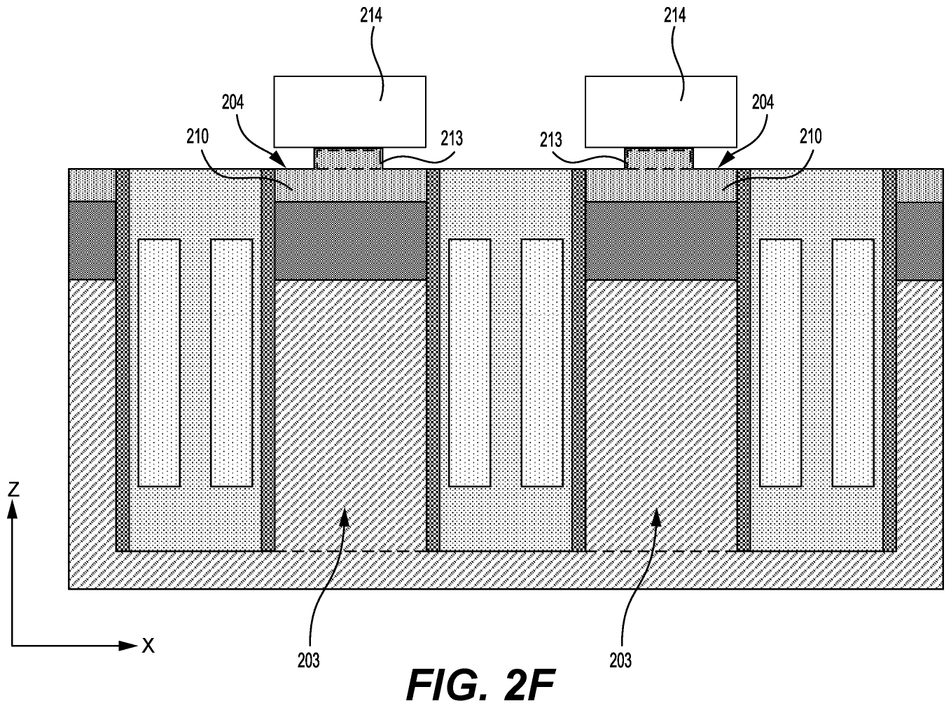

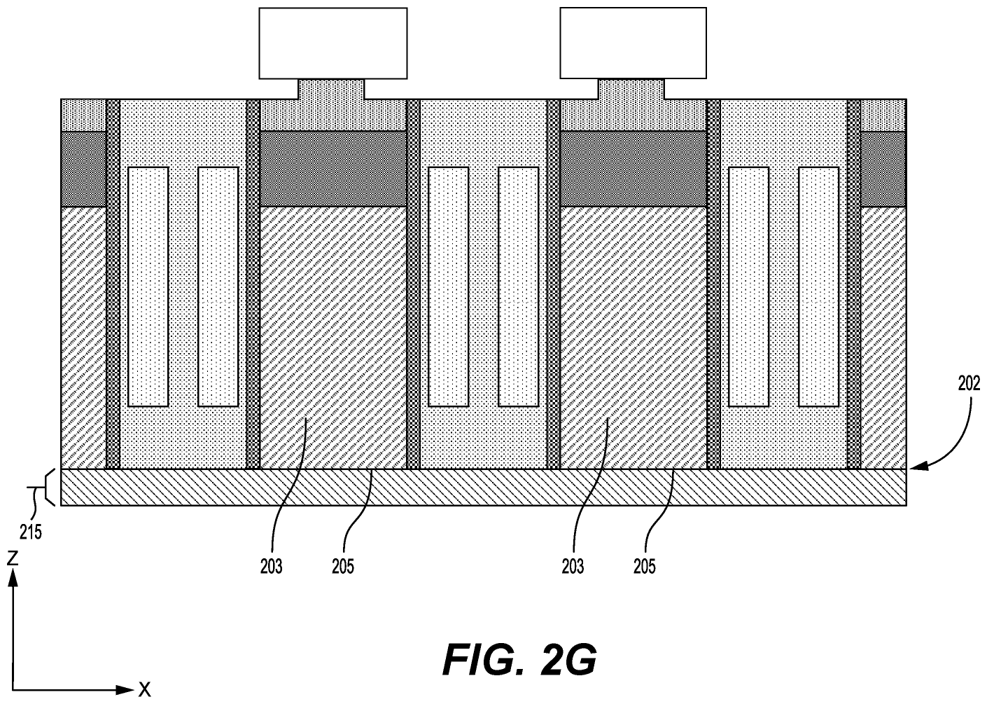

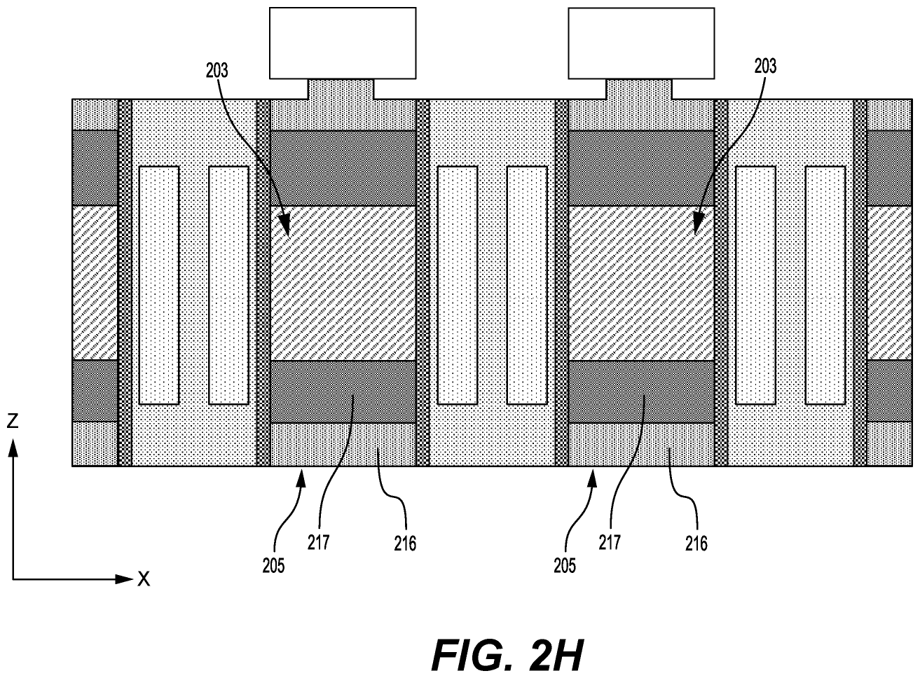

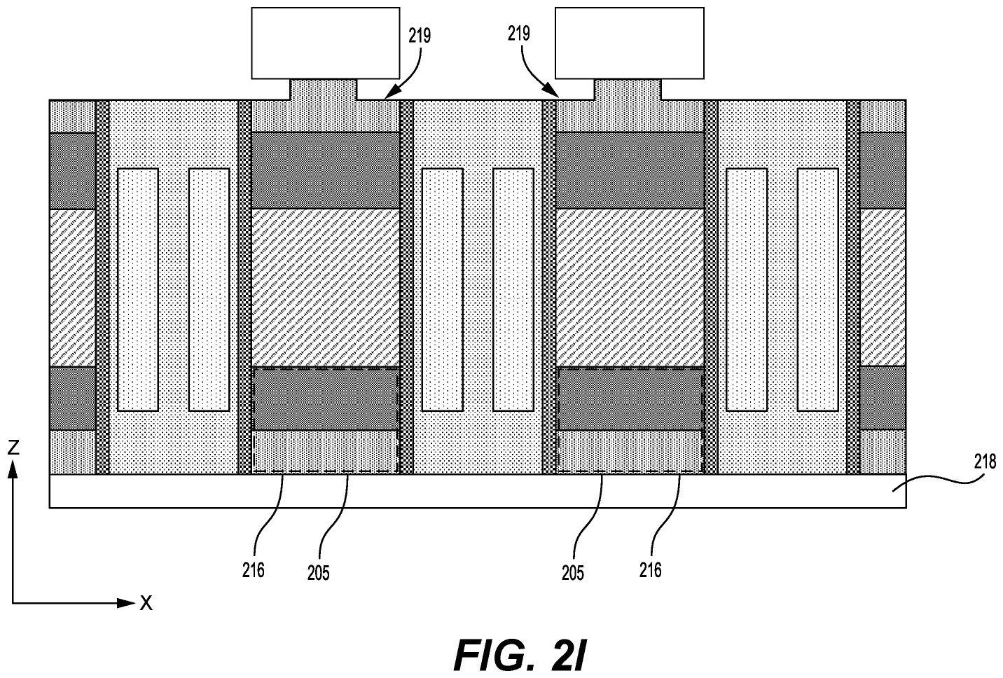

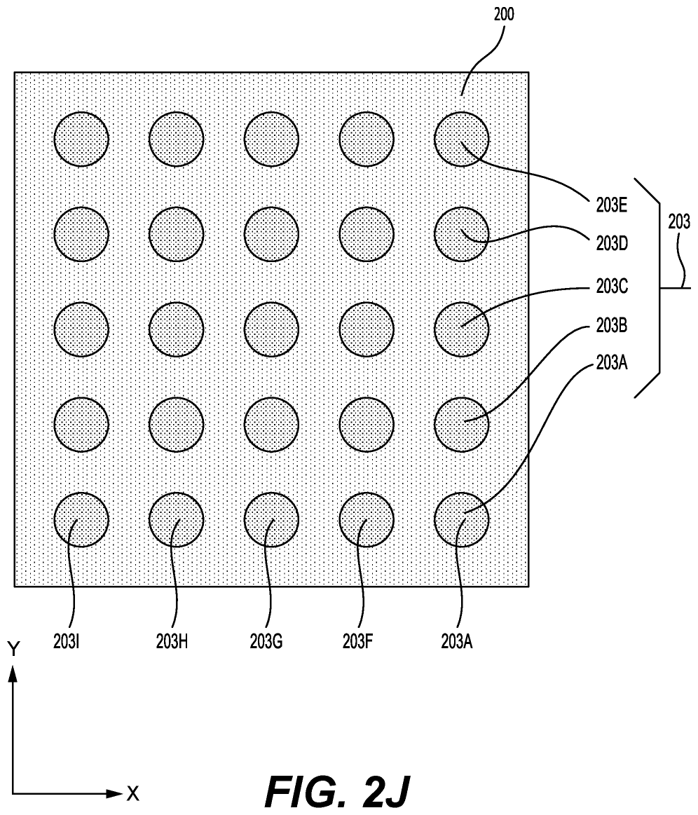

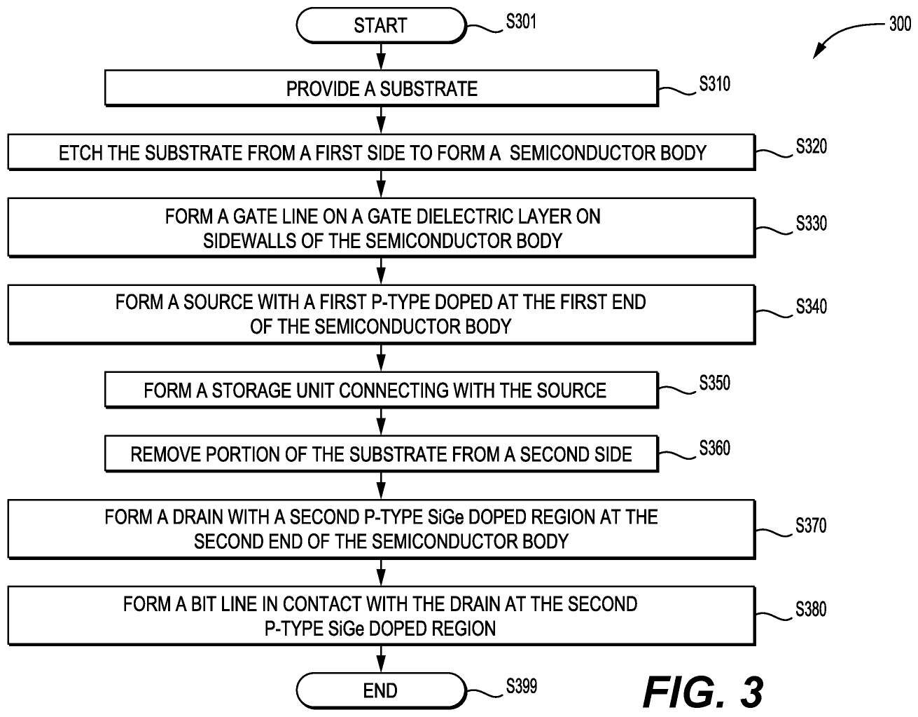

FIGS. 2A-2I show a fabrication process of forming a DRAM array having vertical transistors 219 (shown in FIG. 2I) according to the present disclosure. FIGS. 2A-2I show side views of the cross-section of the DRAM array. FIG. 3 shows a flowchart of the fabrication process 300 of forming the DRAM array having vertical transistors 219 according to the present disclosure. The process 300 can start from S301 and proceed to S310.

At S310 in FIG. 3 and as shown in FIG. 2A, a substrate 200 that can be made of silicon is provided. Other materials, such as germanium, gallium arsenide, indium phosphide, etc. can also be used as the substrate material. The substrate 200 can have a first side 201 and a second side 202.

At S320 in FIG. 3 and as shown in FIG. 2B, a semiconductor body 203 can be formed by etching the substrate 200. The semiconductor body 203 can have a first end 204 and a second end 205. In an embodiment, the etching process can include providing a masking material with patterns on the first side 201 of the substrate 200 and then performing an etching method to remove the desired amount of substrate 200 according to the masking patterns. Trenches 206 and semiconductor body 203 are formed in response to the etching process.

FIG. 2J shows a top view of the substrate 200. The semiconductor body 203 (vertical transistors 203A-2031) can have a substantial shape of a round pillar. Other shapes, such as square pillars and rectangular pillars can also be formed according to the desired masking patterns in an embodiment.

At S330 in FIG. 3 and as shown in FIG. 2C, gate lines 207 can be formed in trench 206 and coupled to a gate dielectric layer 209 of the vertical transistor 219 (shown in FIG. 2I) at the side of the semiconductor body 203. The gate structure can include gate layer and gate dielectric layer 209. The gate dielectric layer is positioned between the gate layer and the semiconductor body 203. The gate lines 207 are formed by connecting gate layers of multiple vertical transistors 219. For example, the gate lines 207 are formed in the y-direction (as shown in FIG. 2J) to couple and connect to columns of the semiconductor bodies 203A, 203B, 203C, 203D, and 203E that are in the y-direction. Oxide filling 208 can be filled into the trench 206 to encapsulate the gate lines 207. The gate structure of the vertical transistor can be formed in a way that is suitable for the memory device. For example, a Gate All Around (GAA) transistor can have the gate structure formed to circumscribe (e.g., surrounding and contacting) all sides of the semiconductor body 203 in the top view. For another example, a multi-gate transistor can have the gate structure in contact with a plurality of sides (e.g., three sides) of the semiconductor body 203.

At S340 in FIG. 3 and as shown in FIG. 2D, a source region including a first p-type doped region 210 is formed at the first end 204 of the semiconductor body 203. The first p-type doped region 210 can connect to a first lightly doped drain (LDD) region 211. For example, the first p-type doped region 210 can be formed by etching away the semiconductor body 203 from the first end 204, then a layer of semiconductor material (e.g., SiGe) can be formed by deposition or epitaxially growing on the semiconductor body 203 followed by doping with a p-type dopant and annealing. For example, the first p-type doped region 210 and the first LDD region 211 can be formed in a similar manner with the LDD region 211 being formed first followed by the first p-type doped region 210. For example, the first p-type doped region 210 can be formed by epitaxially growing a p-typed SiGe on the semiconductor body 203 from the first end 204. The first LDD region 211 can be grown first followed by the first p-type doped region 210 being grown. For example, the first p-type doped region 210 can be formed by depositing a p-typed SiGe directly on the semiconductor body 203 from the first end 204. The first LDD region 211 can be deposited first followed by the first p-type doped region 210 being deposited.

In an embodiment, the first p-type doped region 210 can be doped by diffusion. In an embodiment, the first p-type doped region 210 can be doped by ion implantation. In an embodiment of the present disclosure, the first p-type doped region 210 can be doped using a p-type dopant such as Boron. However, other p-type dopants in the III group elements can also be used. In an embodiment, the first LDD 211 can be a region with a dopant concentration roughly lower than 10¹⁹ atoms/cm³. According to aspects of the present disclosure, the p-type doped region 210 needs to be a heavily-doped region with a dopant concentration higher than 10¹⁹ atoms/cm³. In an embodiment, the first LDD region 211 can be an optional region. For example, the semiconductor body 203 can have only the first p-type doped region 210 at the first end 204.

According to the present disclosure, a dopant activation process is performed after the dopant impurity atoms are diffused or implanted into the semiconductor body 203 to form the first p-type doped region 210. The dopant activation process converts the dopant impurity atoms from a relatively inactive state to an electrically active state. The dopant activation process includes the application of high-temperature annealing, such as rapid thermal annealing. For doped SiGe, the annealing temperature required to activate the dopant depends on the dopant material. For example, p-type SiGe would only require an annealing temperature of 500° C. or less. N-type SiGe would require an annealing temperature of 750° C. or more.

At S350 in FIG. 3 and as shown in FIG. 2E-2F, a storage unit 214 is formed at the first end 204 of the semiconductor body 203. The storage unit 214 is electrically connected to the first p-type doped region 210. In an embodiment, an optional pillar structure 213 can be formed from the first p-type doped region 210. For example, the pillar structure 213 can be formed by removing a thin layer 212 of the substrate 200 at the top side 201 as shown in FIG. 2E. The storage unit 214 can then be formed on the pillar structure 213 and electrically connected to the first p-type doped region 210. In an embodiment, the storage unit 214 can be formed directly on the first p-type doped region 210 and electrically connected to the first p-type doped region 210. The storage unit 214 can include any devices that are capable of storing binary data (e.g., 0 and 1), including but not limited to, capacitors for DRAM cells and FRAM cells, and PCM elements for PCM cells.

At S360 in FIG. 3 and as shown in FIG. 2G, a portion 215 at the second side 202 of the substrate 200 can be removed to expose the second end 205 of the semiconductor body 203.

At S370 in FIG. 3 and as shown in FIG. 2H, a drain region including a second p-type doped region 216 is formed at the second end 205 of the semiconductor body 203. The second p-type doped region 216 can connect to a second LDD region 217. For example, the second p-type doped region 216 and the second LDD region 217 can be formed by etching away the semiconductor body 204 from the second end 205. A layer of semiconductor material (e.g., SiGe) can be formed by deposition or epitaxially growing on the semiconductor body 203 followed by doping with a p-type dopant and annealing. For example, the second p-type doped region 216 and the second LDD region 217 can be formed in a similar manner with the second LDD region 217 being formed first followed by the second p-typed region 216. For example, the second p-type doped region 216 can be formed by epitaxially growing a p-typed SiGe on the semiconductor body 203 from the second end 205. The second LDD region 217 can be grown first followed by the second p-type doped region being grown. For example, the second p-type doped region 216 can be formed by depositing a p-typed SiGe directly on the semiconductor body 203 from the second end 205. The second LDD region 217 can be deposited first followed by the second p-type doped region 216 being deposited.

In an embodiment, the second p-type doped region 216 can be doped by diffusion. In an embodiment, the second p-type doped region 216 can be doped by ion implantation. In an embodiment, the second p-type doped region 216 can be doped using a p-type dopant such as boron. However, other p-type dopants in the III group elements can also be used. In an embodiment, the second LDD region 217 can be a region with a dopant concentration roughly lower than 10¹⁹ atoms/cm³. According to aspects of the present disclosure, the second p-type doped region 216 needs to be a p-type SiGe with a dopant concentration higher than 10¹⁹ atoms/cm³. In an embodiment, the second LDD region 217 can be an optional region. For example, the semiconductor body 203 can have only the second p-type doped region 216 at the second end 205.

According to the present disclosure, a dopant activation process is performed after the dopant impurity atoms are diffused or implanted into the semiconductor body 203 to form the second p-type doped region 216. The dopant activation process converts the dopant impurity atoms from a relatively inactive state to an electrically active state. The dopant activation process includes the application of high-temperature annealing, such as rapid thermal annealing. The annealing temperature required to activate the dopant depends on the dopant material. For example, doping a p-type SiGe would only require an annealing temperature of 500° C. or less. Other dopant materials would require an annealing temperature of 750° C. or more. Since the storage unit 214 is formed at the first end 204 of the semiconductor body 203 as shown in FIG. 2F, an annealing temperature of 500° C. or less to dope the second p-type doped region 216 with p-type SiGe can avoid damage to the storage unit 214.

At S380 in FIG. 3 and as shown in FIG. 2I, bit lines 218 can be formed and connected to the drain region. The bit lines 218 are formed in the x-direction (as shown in FIG. 2I and FIG. 2J) to couple and connect to rows of the semiconductor body 203 (semiconductor body 203A, 203F, 203G, 203H, and 203I) that are in the y-direction. The process 300 can proceed to S399 and terminate at S399.

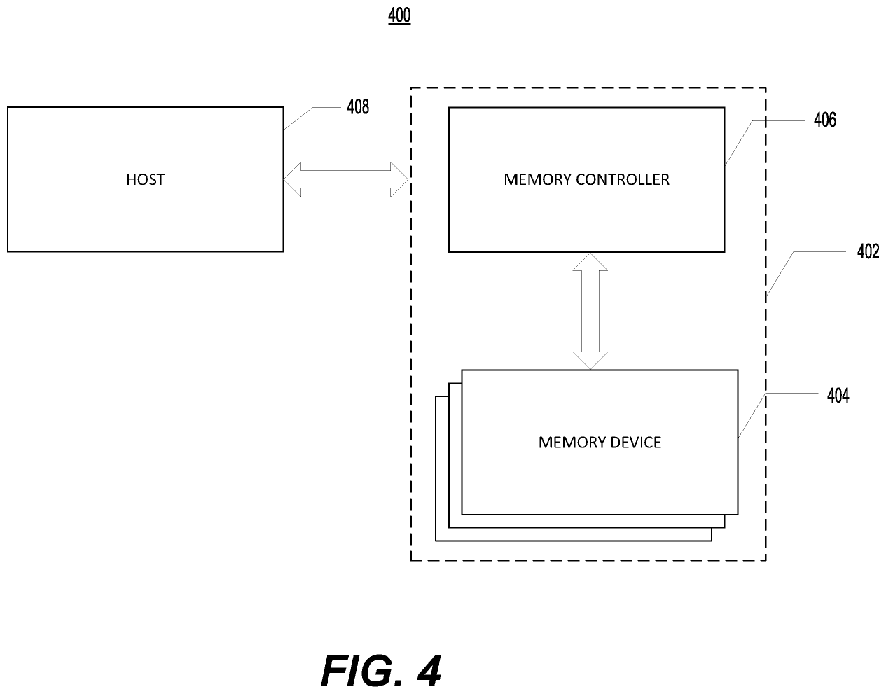

FIG. 4 shows a block diagram of an example system 400 with a memory system according to embodiments of the disclosure. The system 400 can be a mobile phone, desktop computer, laptop computer, tablet computer, vehicle computer, game console, printer, positioning device, wearable electronic device, smart sensor, virtual reality (VR) device, augmented reality (AR) device, or any other suitable electronic device having storage therein.

As shown in FIG. 4, the system 400 can include a host 408 and a memory system 402. The memory system 402 can have one or more memory devices 404 and a memory controller 406. The host 408 can be a processor (e.g., a central processing unit (CPU)) or a system on a chip (SoC) (e.g., an application processor (AP)) of an electronic device. The host 408 can be configured to send data to the one or more memories 404 or receive data from the one or more memories 404.

The one or more memories 404 can be any memory device disclosed in the present disclosure, for example, the one or more memories 404 can include the memory device 100 provided by the present disclosure. As disclosed in detail below, the one or more memories 404 (e.g., DRAM device) can have a vertical transistor structure that at least uses p-type SiGe at the drain region for bit line connection.

In an embodiment, the memory controller 406 is coupled to the one or more memories 404 and the host 408 and is configured to control the one or more memories 404. The memory controller 406 can manage data stored in the one or more memories 404 and communicate with the host 408. The memory controller 406 is configured to control the one or more memories 404 to perform the programming method provided by any of the implementations of the present disclosure.

In an embodiment, the memory controller 406 is designed for operation in a main memory that is used as a instructions and data store when a program is executing for electronic devices such as personal computers, digital cameras, mobile phones, tablet computers, and so forth. The memory controller 406 can be configured to control operations of the memory device 404, such as read, erase, and program operations. The memory controller 406 can also be configured to manage various functions with respect to data stored or to be stored in the memory device 404.

The memory controller 406 can communicate with external devices (e.g., the host 408) according to a particular communication protocol.

The memory controller 406 and the one or more memories 404 can be integrated into various types of storage devices, for example, included in the same package (e.g., DDR SDRAM). The memory system 402 can be implemented and packaged into different types of end electronics.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. A method of fabricating a semiconductor device, comprising:
providing a substrate;
etching the substrate from a first side of the substrate to form at least one vertical pillar, the at least one vertical pillar has a first end and a second end opposite to the first end;
forming at least one gate line on a gate dielectric layer formed on sidewalls of the at least one vertical pillar;
forming a first p-type region at the first end of the at least one vertical pillar;
forming a storage unit connecting the first p-type region;
removing a portion of the substrate at a second side of the substrate to expose the second end of the at least one vertical pillar, the second side of the substrate being opposite to the first side of the substrate;
forming a second p-type region at the second end of the at least one vertical pillar, the second p-type region is made of at least p-type silicon germanium (SiGe); and
forming a bit line in connection with the second p-type region at the second end of the at least one vertical pillar.

2. The method of claim 1, wherein the forming the second p-type region further comprises:
performing a thermal annealing process with an annealing temperature of less than 500° C.

3. The method of claim 1, wherein the forming the second p-type region further comprises:
epitaxing the p-type SiGe onto the at least one vertical pillar.

4. The method of claim 1, wherein the forming the second p-type region further comprises:
depositing the p-type SiGe onto the at least one vertical pillar.

5. The method of claim 1, wherein the first p-type region has a dopant concentration higher than 10¹⁹ atoms/cm³.

6. The method of claim 1, wherein the second p-type region has a dopant concentration higher than 10¹⁹ atoms/cm³.

7. The method of claim 1, wherein the at least one gate line and the bit line are formed so that they are perpendicular to each other.

8. The method of claim 1, wherein the at least one gate line is encapsulated by an oxide layer.

9. The method of claim 1, wherein the storage unit is a capacitor.

10. A semiconductor device, comprising:
at least one vertical pillar, the at least one vertical pillar has a first end and a second end opposite to the first end;
at least one gate line on a gate dielectric layer formed on sidewalls of the at least one vertical pillar;
a first p-type region at the first end of the at least one vertical pillar;
a storage unit connects with the first p-type region;
a second p-type region at the second end of the at least one vertical pillar, the second p-type region comprises at least p-type silicon germanium (SiGe); and
a bit line in connection with the second p-type region at the second end of the at least one vertical pillar.

11. The semiconductor device of claim 10, wherein the first p-type region has a dopant concentration higher than 10¹⁹ atoms/cm³.

12. The semiconductor device of claim 10, wherein the second p-type region has a dopant concentration higher than 10¹⁹ atoms/cm³.

13. The semiconductor device of claim 10, wherein the gate line and the bit line are formed so that they are perpendicular to each other.

14. The semiconductor device of claim 10, wherein the gate line is encapsulated by an oxide layer.

15. The semiconductor device of claim 10, wherein the storage unit is a capacitor.

16. A memory system, comprising:
a semiconductor device configured to store data, and comprising:
at least one vertical pillar, the at least one vertical pillar has a first end and a second end opposite to the first end;
at least one gate line on a gate dielectric layer formed on sidewalls of the at least one vertical pillar;
a first p-type region at the first end of the at least one vertical pillar;
a storage unit connects with the first p-type region;
a second p-type region at the second end of the at least one vertical pillar, the second p-type region comprises at least p-type silicon germanium (SiGe); and
a bit line in connection with the second p-type region at the second end of the at least one vertical pillar; and
a memory controller coupled to the semiconductor device and configured to control the semiconductor device through the at least one gate line and the bit line.

17. The memory system of claim 16, wherein the at least one gate line and the bit line are perpendicular to each other.

18. The memory system of claim 16, wherein the storage unit is a capacitor.

19. The memory system of claim 16, wherein the first p-type region has a dopant concentration higher than 10¹⁹ atoms/cm³.

20. The memory system of claim 16, wherein the second p-type region has a dopant concentration higher than 10¹⁹ atoms/cm³.
